(19) United States
(12) Patent Application Publication
(10) Pub. No.: US 2001/0040260 A1
(43) Pub. Date: Nov. 15, 2001

(54) HIGH-RESISTANCE LOAD SRAM

(76) Inventor: HIDETAKA NATSUME, TOKYO (JP)

Correspondence Address: FOLEY & LARDNER, 3000 K STREET N W SUITE 500, P O BOX 25696, WASHINGTON, DC, 200078696

(21) Appl. No.: 09/160,796

(22) Filed: Sep. 25, 1998

(30) Foreign Application Priority Data
Sep. 26, 1997 (JP) 9-262078

(51) Int. Cl. H01L 29/94; H01L 31/113; H01L 31/119; H01L 29/76; H01L 31/062

(52) U.S. Cl. 257/393

(57) ABSTRACT

A SRAM includes a plurality of high-resistance memory cells each having a point symmetric structure. The memory cell has a pair of load resistors each implemented by a contact plug. Each of the contact plugs connects the drain of a first drive transistor and the gate of a second drive transistor with a source line. The source/drain region of each transfer transistor is connected to a bit line implemented by a fourth layer alumninum via a contact plug received in a through-hole having a side wall for insulating the contact plug from the ground line implemented as a third layer polysilicon film.

### BACKGROUND OF THE INVENTION

1. Field of the Invention

The present invention relates to a high-resistance load static random access memory (SRAM) ad, more particularly to an improvement of a SRAM having a high-resistance load made of a polycrystalline silicon (polysilicon) layer and a CMOS transistor.

2. Description of the Related Art

SRAM has been widely used as storage means in various semiconductor devices. A typical SRAM includes a plurality of memory cell arranged in matrix each for storing data “high” or “low”. A high-resistance load SRAM cell one of typical SRAM cells, generally has a polysilicon film implementing a pair of high-resistance loads, which provides a simple structure for the SRAM.

Referring to FIG. 1, a typical SRAM cell generally has a flipflop including first and second inverters connected in parallel between a source line Vcc and a ground line. The first inverter has a fist high-resistance load R1 and a first drive transistor (MOSFET or IGFET) T1 connected in series, whereas the second inverter has a second high-resistance load R2 and a second drive transistor T2 connected in series. The first memory node A1 connecting an end of the first high-resistance load R1 and the drain of the first drive transistor T1 together is connected to the gate of the second drive transistor T2, whereas the second memory node A2 connecting an end of the second high-resistance load R2 and the drain of the second drive transistor T2 together is connected to the gate of the first drive transistor T1.

The first memory node A1 is connected to a first bit line BL via the source/drain path of a first transfer transistor T3 having a gate implemented as a word line W1. The second memory node A2 is connected to a second bit line rBL via the source/drain path of a second transfer transistor T4 having a gate implemented as a word line W2, which receives a common signal with the word line W1. The first bit line BL and the second bit line rBL receive a pair of complementary signal.

Referring to FIG. 2, there is shown a cross-sectional view of the first memory node A1, which is similar to that of the second memory node A2. An n-type diffused region 322 formed on a silicon substrate 301 constitutes the drain of the first drive transistor T1 and one of the source/drain regions (or first source/drain region) of the first transfer transistor T3 as well as a shared contact region. A through-hole 352 formed in a interlayer dielectric films 341 and 342 receives therein a contact plug 373 which connects a high-resistance load layer 371 and the gate electrode 332 of the second drive transistor T2 with the n-type diffused region at the bottom of the through-hole 352.

FIG. 3 shows an exemplified top plan view of the memory cell shown in FIG. 2. FIG. 2 is taken along line II-II in FIG. 3. The structure shown in these drawings is described in JP-A63(1988)-193558, for example. The drive transistor T1 has a source implemented by an n-type diffused region 321 connected to the ground line, a drain implemented by the n-type diffused region 322 and a gate 331 implemented by a first layer polysilicon film. The second drive transistor has a source implemented by an n-type diffused region 325 connected to the ground line, a drain implemented by a n-type diffused region 324 and a gate 332 implemented by the first layer polysilicon film.

The first transfer transistor T3 has the first source/drain region implemented by the n-type diffused region 322, a second source/drain region implemented by an n-type diffused region 323 connected to the first bit line BL and a gate implemented by a second layer polysilicon film, which intersects the first layer polysilicon film with an intervention of an interlayer insulation film and constitutes a part of a word line 333.

The second transfer transistor T4 has a first source/drain region implemented by the n-type diffused region 324, a second source/drain region implemented by an n-type diffused region 326 connected to the second bit line rBL and a gate implemented by the second layer polysilicon film, which constitutes another part of the word line 333.

The first high-resistance load (or load resistor) R1 implemented by a third layer polysilicon film 371a is connected to the n-type diffused region 322 in the shared contact hole 352a through the contact plug which constitutes the first memory node A1. The second high-resistance load R2 implemented by the third layer polysilicon film 371b is connected to the n-type diffused region 324 in the shared contact hole 352b through the contact plug which constitutes the second memory node A2. Above the contact plug and the high-resistance load layer, a ground layer implementing the ground line and a bit line layer implementing the bit lines BL and rBL are consecutively formed on the memory cell.

In the structure shown in FIG. 3, the memory cell is of a point symmetry with respect to a point 400, wherein both the drive transistors T1 and T2, both the transfer transistors T3 and T4, and both the high-resistance loads R1 and R2 are respectively point symmetric to each other with respect to the point 400.

The shared contact structure as describe above has the advantage of low contact resistance, whereas the point symmetric structure has the advantage of an excellent balance with respect to the potential and the current within the memory cells thereby improving the reliability of the SRAM in the data storage function.

The structure of the SRAM as described above, however, necessitates a five-layer structure when a contact plug is formed every one bit cell or two bit cells. The five layer structure including the first layer polysilicon film for the gates of the drive transistors, the second layer polysilicon film for the gates of the transfer transistors, the third layer polysilicon film for the high-resistance loads, a fourth layer polysilicon film for the ground line and a fifth layer aluminum film for the bit lines causes a complicated process for fabrication of the SRAM.

### SUMMARY OF THE INVENTION

It is an object of the present invention to provide a SRAM having a less number of conductive layers substantially without degrading the characteristics of the SRAM.

The present invention provides a SRAM comprising a semiconductor substrate, a plurality of memory cells ranged in a matrix on the semiconductor substrate, a pair of bit lines disposed for each column of the memory cells, and a word line disposed for each row of the memory cells.

Each of the memory cells includes first and second drive transistors each having a source connected to a ground line, a drain implemented by a first diffused region and a gate, a first transfer transistor having a first source/drain region implemented by the first diffused region of the first drive transistor, a second source/drain region connected to one of the bit lines and a gate connected to corresponding the word line, a second transfer transistor having a first source/drain region implemented by the first diffused region of the second drive transistor, a second source/drain region connected to the other of the bit lines and a gate connected to corresponding the word line, a first resistor implemented by a first contact plug connecting the first diffused region of the first drive transistor and the gate of the second drive transistor with a source line, and a second resistor implemented by a second contact plug connecting the fist diffused region of the second drive transistor and the gate of the first drive transistor with the source line.

In accordance with the SRAM of the present invention, the SRAM can be manufactured in a four-layer structure, which reduces the fabrication steps of the SRAM and provides a simplified structure thereof.

The above and other objects, features and advantages of the present invention will be more apparent from the following description, referring to the accompanying drawings.

### BRIEF DESCRIPTION OF THE DRAWINGS

FIG. 1 is a circuit diagram of a typical high-resistance load SRAM.

FIG. 2 is a cross-sectional view of a conventional SRAM;

FIG. 3 is a top plan view of the conventional SRAM of FIG. 2;

FIG. 4 is a top plan view of a SRAM according to an embodiment of the present invention; and

FIG. 5 is a cross-sectional view taken along line V-V in FIG. 4.

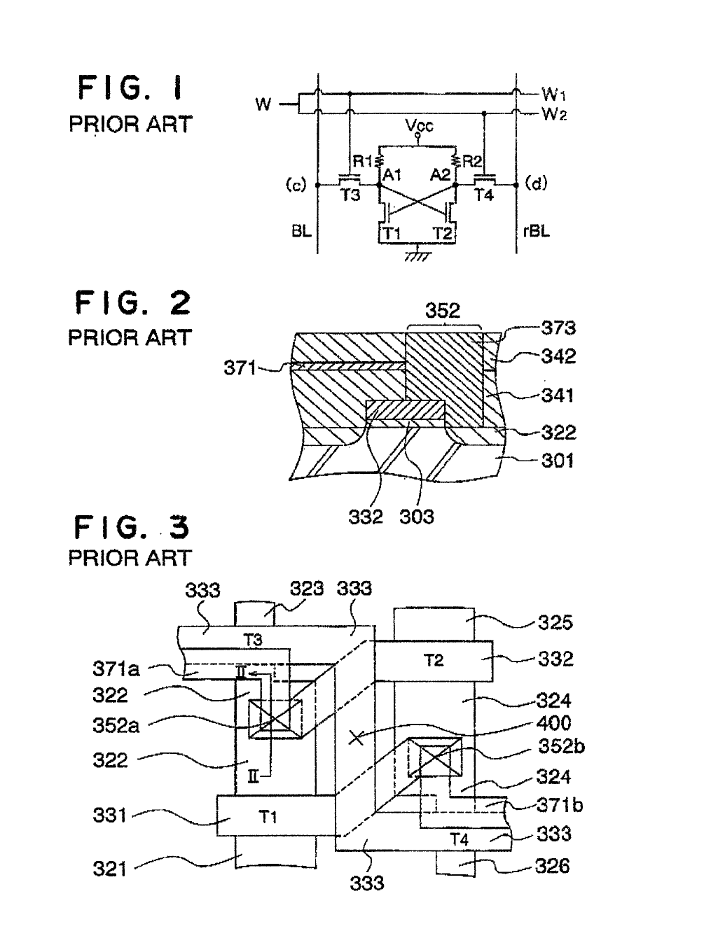

### PREFERRED EMBODIMENTS OF THE INVENTION

Now, the present invention is more specifically described with reference to accompanying drawings.

A SRAM according to a first embodiment of the present invention has a circuit configuration as described above with reference to FIG. 1. More specifically, the SRAM has a flipflop including first and second inverters connected in parallel between a source line Vcc and a ground line. The first inverter has a first high-resistance load R1 and a first drive transistor (MOSFET or IGFET) T1 connected in series, whereas the second inverter has a second high-resistance load R2 and a second drive transistor T2 connected in series The first memory node A1 connecting an end of the first high-resistance load R1 and the drain of the first drive transistor T1 together is connected to the gate of the second drive transistor T2, whereas the second memory node A2 connecting an end of the second high-resistance load R2 and the drain of the second drive transistor T2 together is connected to the gate of the first drive transistor T1.

The first memory node A1 is connected to a first bit line BL via the source/drain path of a first transfer transistor T3 having a gate implemented as a word line W1. The second memory node A2 is connected to a second bit line rBL via the source/drain path of a second transfer transistor T4 having a gate implemented as a word line W2, which receives a common signal with the word line W1. The first bit line BL and the second bit line rBL receive a pair of complementary signal.

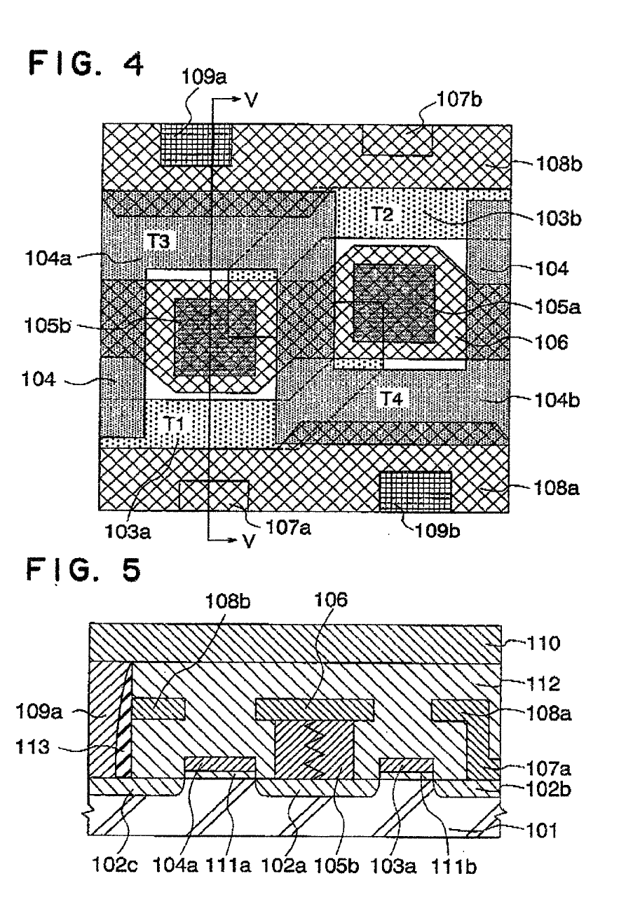

Referring to FIGS. 4 and 5, the first drive transistor T1 is formed on a silicon substrate 101, and has a source implemented by an n-type diffused region 102b, a drain implemented by an n-type diffused region 102a and a gate 103a implemented by a first layer polysilicon film formed on the silicon substrate 101 with an intervention of a gate oxide film 111b. The gage 103b of the first drive transistor T1 extends toward above the diffused region of the second drive transistor T2 and the second transfer transistor T4. The second drive transistor T2 has a structure similar to that of the first drive transistor, and includes a gate 103b implemented by the first layer polysilicon and extending toward above the diffused region 105b of the first drive transistor T1 and the first transfer transistor T2.

The first transfer transistor T3 has a first source/drain region implemented by the n-type diffused region 102a common to the drain of the first drive transistor T1, a second source/drain region implemented by an n-type diffused region 102c, and a gate 104a implemented by a second layer polysilicon film which intersects the first layer polysilicon film with an intervention of an interlayer dielectric film 112 and constitutes a part of a word line 104. The second transfer transistor T4 has a structure similar to that of the fist transfer transistor T3, and has a gate 104b implemented by the second layer polysilicon film which constitutes another part of the word line 104.

A first shared contact plug 105b connects an end of the gate 103b of the second dive transistor T2 and the n-type diffused region 102a for the first drive transistor T1 and the first transfer transistor T3 with a source line 106 which constitutes a high-voltage source Vcc. Similarly, a second shared contact plug 105a connects an end of the gate of the first drive transistor T1 and the diffused region for the second drive transistor T2 and the second transfer transistor T4 with the source line 106. The shared contact plugs 105a and 105b are made of high-resistance polysilicon to constitute the first high-resistance load (or load resistor) R1 and the second high-resistance load R2, respectively.

The source 102b of the first drive transistor T1 is connected to a ground line 108a via a ground contact 107a, whereas the source of the second drive transistor T2 is connected to a ground line 108b via a ground contact 107b.

The n-type diffused region 102c of the first transfer transistor T3 is connected to the first bit line 110 via a bit contact plug 109a, whereas the corresponding n-type diffused region of the second transfer transistor T4 is connected to the second bit line not shown. The gates 103a and 104a are formed on the gate oxide films 111b and 111a, respectively, in different steps as the layer polysilicon film and the second layer polysilicon film, respectively. The through-holes receiving therein the bit contact plugs 109a and 109b have side walls 113 formed therein for insulating the bit contact plug 109a and 109b from the ground line 108b and 108a.

In the SRAM according to the present embodiment, the high-resistance loads R1 and R2 in the memory cell are implemented by the contact plugs 105a and 105b, as a result of which the source line 106 and the ground line can be implemented by a common conductive layer. Further, the structure that the bit contact plugs 109a and 109b penetrate through the ground lines 108b and 108a enables a four-layer structure for the conductive layers.

More specifically, the conductive layers include the first layer polysilicon film implementing the gates 103a and 103b of the drive transistors T1 and T2, the second layer polysilicon film implementing the word line 104 including the gates 104a and 104b of the transfer transistors, the third layer polysilicon film implementing the source line 106 and the ground lines 108a and 108b, and the fourth layer aluminum film implementing the bit lines 110.

Since the above embodiments are described only for examples, the present invention is not limited to the above embodiments and various modifications or alterations can be easily made therefrom by those skilled in the art without departing from the scope of the present invention.

What is claimed is:

1. A SRAM comprising a semiconductor substrate, a plurality of memory cells arranged in a matrix on said semiconductor substrate, a pair of bit lines disposed for each column of said memory cells, and a word line disposed for each row of said memory cells,
each of said memory cells including first and second drive transistors each having a source connected to a ground line, a drain implemented by a first diffused region and a gate, a first transfer transistor having a first source/drain region implemented by said first diffused region of said first drive transistor, a second source/drain region connected to one of said bit lines and a gate connected to corresponding said word line, a second transfer transistor having a first source/drain region implemented by said first diffused region of said second drive transistor, a second source/drain region connected to the other of said bit lines and a gate connected to corresponding said word line, a first resistor implemented by a first contact plug connecting said first diffused region of said first drive transistor and said gate of said second drive transistor with a source line, and a second resistor implemented by a second contact plug connecting said fist diffused region of said second drive transistor and said gate of said first drive transistor with said source line.

2. A SRAM as defined in claim 1, wherein said gate of said drive transistors sad gate of said transfer transistors as well as said word line, said ground line as well as said source line, and said bit lines are implemented by a first, second, third and fourth layer conductive films.

3. A SRAM as defined in claim 2, wherein sad first through third layer conductive films are made of polycrystalline silicon and said fourth layer conductive film is made of aluminium.

4. A SRAM as defined in claim 2, each of said second source/drain regions of said transfer transistors are connected to said bit lines via a third contact plug formed in a through-bole having a side wall insulating said third contact plug from said ground line.
